(19) United States
(12) Patent Application Publication
(10) Pub. No.: US 2009/0211951 A1
(43) Pub. Date: Aug. 27, 2009

(54) Device and Method for Continuously Producing a Defective-Free Carrier Strip

(75) Inventors: Martin Bohn, Reutlingen (DE); Harry Nitschko, Wolfschlugen (DE)

Correspondence Address: K.F. ROSS P.C., 5683 RIVERDALE AVENUE, SUITE 203 BOX 900, BRONX, NY, 10471-0900, US

(73) Assignee: BIELOMATIK LEUZE GMBH & CO. KG, Neuffen (DE)

(21) Appl. No.: 11/990,897

(22) PCT Filed: Jul. 19, 2006
(86) PCT No.: PCT/EP2006/007084

§ 371 Date: Feb. 12, 2009

(30) Foreign Application Priority Data
Aug. 23, 2005 (DE) 10 2005 041 024.3

(51) Int. Cl. H05K 13/08

(52) U.S. Cl. 209/552

(57) ABSTRACT

The invention relates to a device (1) for continuously selecting defective components (2) from a certain amount of components (2) which are arranged in a detachable manner on a carrier strip (3) in at least one continuous row, and a device (80) and method for continuously producing a carrier strip (3), which is void of defects, from a carrier strip (3) whereon components (2) are arranged in at least one continuous row, and which comprises defective components (2) and components which are void of defects (2). Said device (1) for continuously selecting defective components (2) comprises a control device (10) which is used to determine defective components, a transfer device (20) which is used to transfer selected, defective components (2), at least one separation device (30, 31, 32), which at least partially separates each component (2) from the carrier strip (3) and replaces it in an offset manner in relation to the preceding position on the carrier strip (3), and at least one selection device (40), which selects a component (2) which is determined as defective by the control device (10) and at least partially separates it from the carrier strip (3) in such a manner that said component is removed by the transfer device (20). Said device can be used, for example, in the production of labels (smart labels).

The invention relates to an apparatus for continuously separating defective components from a number of components that are removably mounted on at least one carrier strip and in at least one continuous row as well as an apparatus and method of continuously producing a defect-free carrier strip from a carrier strip with at least one continuous row of components arranged thereon, with the carrier strip having defective and defect-free components.

In the production of endless carrier strips on which components are arrayed in continuous rows, it is normally required that only functional and/or defect-free components be on the carrier strip. This is the case, for example, when the carrier strip is supplied as an endless roll in an automatic dispenser and the components are electronic information carriers that, for example, identify a pallet or package.

Normally, as a preliminary stage of the production of a defect-free carrier strip of this type, there is a carrier strip on which defective and defect-free components have been mounted. The defect rate is normally determined using the production rejects from the production of the components.

EP 1 096 423 A2 [U.S. Pat. No. 6,588,476] discloses methods and apparatuses for the production of a defect-free carrier strip of this type.

In a first variant described there, the defect-free carrier strip is produced using two carrier strips on each of which defective and defect-free components have been removably mounted. On the first carrier strip, only defective components are separated from the strip and subsequently removed by a separator apparatus. From the second carrier strip, only defect-free components are removed; they are then placed in gaps on the first carrier strip left by the removal of the defective components. After the replacement process, the first carrier strip is free of defects.

In a second variant, a first carrier strip is provided upon which again defective and defect-free components are mounted. Moreover, a second, empty carrier strip is provided. In order to produce the defect-free carrier strip, first all components are removed from the first carrier strip. Out of the components that were removed, in a selection process, only defect-free components are transferred onto the second, empty carrier strip, which then becomes the defect-free carrier strip.

Due to the selective removal and/or transfer processes, however, it is possible in both of these variants for operating conditions to occur in which the speed of one carrier strip must be reduced in order to guarantee reliable operation.

The object of the invention is therefore to provide an apparatus for the continuous rejection of defective components and an apparatus and method of the continuous production of a defect-free carrier strip that allows reliable operation at high speeds.

This object is attained according to the invention by an apparatus for the continuous rejection of defective components according to claim 1, an apparatus for the continuous production of a defect-free carrier strip according to claim 13, and a method of the continuous production of a defect-free carrier strip according to claim 17.

The apparatuses and the method have in common that the components are removably mounted on the carrier strip. In other words, they bay be removed from the carrier strip and subsequently reapplied without causing any damage. Silicon-coated paper or the like, for example, may be used as the material for the carrier strip. An adhesive may be applied to the components and/or the carrier strip that forms a detachable connection between the carrier strip and the component.

The apparatus for the continuous rejection of defective components includes a monitoring apparatus for detecting defective components and a transfer device for transferring defective components to be rejected. The monitoring apparatus may use various criteria for discerning the status of a component. If the components are electronic components with a memory that may be read without contact, it is possible, for example, for the serial number of the electronic component or special memory contents to be verified via a radio interface. As an alternative or in addition to this, a response speed of the electronic component being brought into an electromagnetic field or the like may be used. Optical monitoring by means of cameras in conjunction with image processing algorithms may also be used to detect a defective component. The transfer device removes a defective component from the carrier strip and transports it to be further processed, for example, to be recycled or disposed of. According to the invention, at least one stripper that separates each component at least partially from the carrier strip and replaces it on the carrier strip offset relative to a preceding position, and at least one selector that selects a component that has been detected by the monitoring apparatus as being defective and at least partially separated from the carrier strip in such a way that it is removed by the transfer device, are provided. Because each component is gently separated from the carrier strip in this manner and, if the component is not defective, reattached to the carrier strip in an offset position, a selective separation process dependent upon the condition of the component that may require reduction in the speed of the carrier strip is not necessary. This means that the separation process is able to take place at full speed. This increases the throughput of an apparatus of this type. Here, the stripper and the selector operate in an integrated manner in such a way that, in order to select it, a defective, partially separated component is subjected to a force in such a way that it is deflected toward the transfer device, so that a removal is effected. Here, a defect-free component is not subjected to such a force, so that it is attached again by its separated region to an offset section of the carrier strip.

In a further development, the stripper includes an upstream carrier-strip deflector, with the carrier strip being guided over the upstream carrier-strip deflector and the upstream carrier-strip deflector, by deflecting the carrier strip out of a transport direction and into a separation direction, causing the partial separation of the component in the transport direction.

Moreover, the stripper preferably includes a downstream carrier-strip deflector, with the carrier strip being guided over the upstream carrier-strip deflector and the downstream carrier-strip deflector, the downstream carrier-strip deflector causing a deflection of the carrier strip in the transport direction in an associated deflection section and, in the deflection section, the component, which has been at least partially separated from the carrier strip, being reattached to the carrier strip. The upstream and downstream carrier-strip deflectors allow for a simple detachment or peeling off and a subsequent offset attachment of the defect-free components on the carrier strip. In addition, it is preferable for the stripper to include a deflection roller, with the carrier strip being guided over the upstream carrier-strip deflector, the deflection roller, and the downstream carrier-strip deflector. This allows the transport strip to be controlled in a simple and flexible manner, with the position of the deflection roller relative to the carrier strip deflectors being adjustable to conform to various parameters, for example, a degree of offset. Preferably, the upstream carrier-strip deflector has an upstream face in the transport plane of the carrier strip and the downstream carrier-strip deflector has a downstream face also in the transport plane of the carrier strip, with a gap being formed between the upstream face and the downstream face and a rotational axis of the deflection roller being located outside the transport plane. The edges of the upstream and downstream face delimiting the gap are preferably parallel. Here, the rotational axis of the deflection roller may run parallel to the edges in the horizontal direction in the center of the gap and in the vertical direction offset from the transport plane by a distance that is greater than the diameter of the deflection roller.

In a further development, the selector includes a push-up roller with which a defective component that has been at least partially separated from the carrier strip for selection may be deflected toward the transfer device. The push-up roller may, for example, press against a region of the component that has been separated from the carrier strip, which as the result of the effect of force is moved or bent toward the transfer device. Alternately or additionally, the selector includes a compressed-air device by means of which a defective component that has been at least partially separated from the carrier strip is blown toward the transfer device for removal.

In a further development, the transfer device has a transfer roller for transferring defective components. Preferably, the transfer roller has air circulation openings distributed over its outer surface and serving to apply a controllable subatmospheric or superatmospheric pressure that causes a defective component that has been transferred to adhere or separate. A structure of this kind carries out transfer and removal of a defective component because the component is pulled onto the transfer roller by the low pressure. The controllable low pressure may be switched off or converted to high pressure at an appropriate position of the roller, for example, when stripping off the defective component, so that removal of the component is facilitated. Preferably, a collector roller in active connection with the transfer roller is provided for receiving defective components, with a defective component being transferred from the transfer roller to the collector roller. The collector roller may collect the defective components in several positions, with the transfer roller being returned to its functional state by the defective components being stripped off.

In a further development, a pressure roller is provided that presses a component that has been returned back onto the carrier strip. When a defect-free component is first separated from the carrier strip by the stripper and is subsequently replaced on the carrier strip in an offset position, the adhesion of the component to the carrier strip is initially reduced. However, reduced adhesion carries the danger that the component will detach in an undesired fashion in subsequent sections of the carrier strip, for example, in the region of the carrier strip deflections. In order to compensate for this effect, the component is pressed down, so that the original degree of adhesion is approximately restored.

In a further development, the components are arrayed in several rows on the carrier strip and each row is assigned to a selector. The rows may then share the monitoring apparatus, the transfer device, and the stripper. However, because the order of the defective and/or defect-free components may be different between the individual rows, one selector is provided for each row. The arrangement of the components in multiple rows on the carrier strip allows for parallel processing, i.e. the possible throughput increases approximately proportionally to the number of rows.

The apparatus according to the invention for the continuous production of a defect-free carrier strip includes an apparatus according to the invention described above for the continuous removal of defective components and at least one dispenser that inserts a defect-free component into the spaces of the carrier strip from which a defective component has been removed. Preferably, in order to achieve higher supply speeds, multiple dispensers are used that preferably are arrayed one behind the other in the supply direction. The combination of a removal apparatus and dispensers allows a defect-free carrier strip to be produced at a high speed because it is possible to remove defective components without reducing the speed of the carrier strip.

In a further development, the dispenser is gas another carrier strip that contains only defect-free components.

In a further development, the components are transponders. Preferably, a programming unit is provided that programs the transponders on the defect-free carrier strip. The transponders are preferably used in transponder labels.

In the method according to the invention for the continuous production of a defect-free carrier strip, each component is at least partially separated from the carrier strip, a defective and at least partially separated component is removed, a defect-free component is reapplied to the carrier strip in an offset position, and a removed component is replaced by a defect-free component.

In a further development, the speed of the carrier strip is constant.

Other advantages and features of the invention may be found in the claims as well as in the following description of preferred illustrated embodiments of the invention, which are shown schematically with reference to the drawings. Therein:

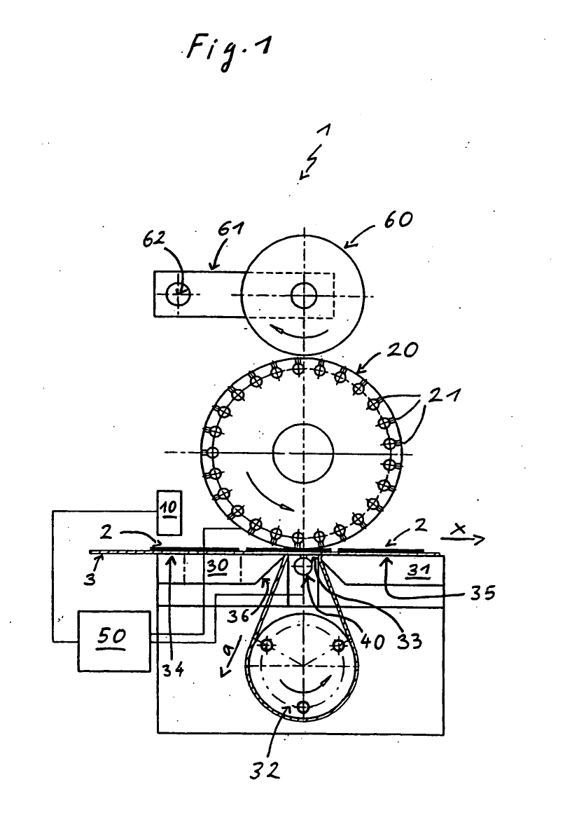

FIG. 1 shows an apparatus for the continuous separation of defective transponders in a case in which separation is not necessary;

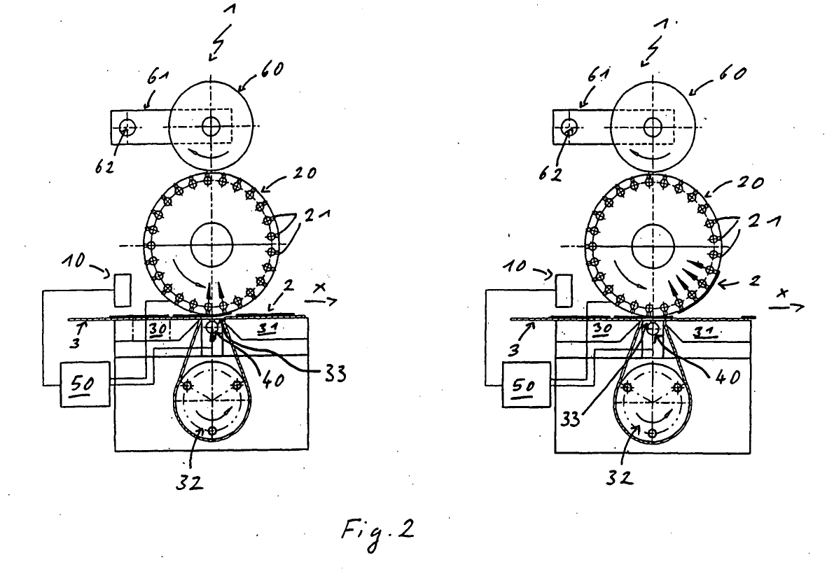

FIG. 2 shows the apparatus for the continuous separation of defective transponders of FIG. 1 in a situation where the separation of a defective transponder is necessary;

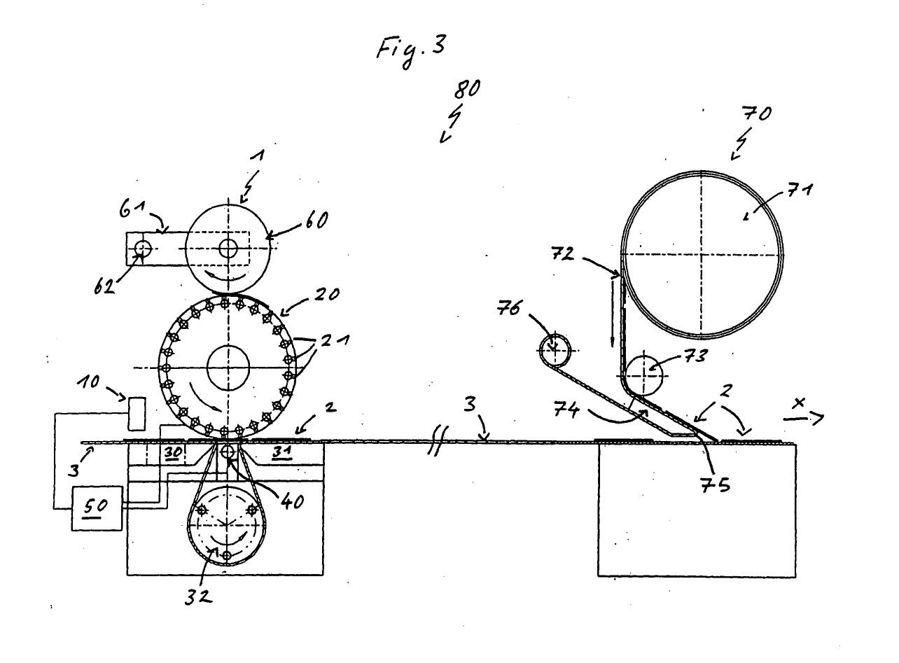

FIG. 3 shows an apparatus for the continuous production of a defect-free carrier strip with the apparatus for continuous separation of FIG. 1; and

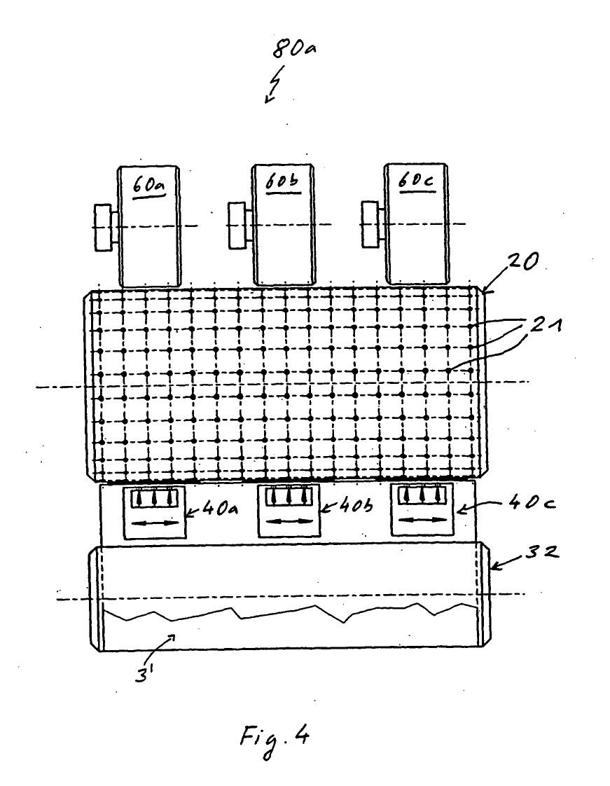

FIG. 4 shows an apparatus for the continuous production of a defect-free carrier strip where transponders are arrayed in multiple rows on the carrier strip.

FIG. 1 shows an apparatus 1 for the continuous separation of defective components in the form of transponders from a multiplicity of transponders 2 that are mounted equidistantly and removably on a carrier strip 3. The transponders 2 are mounted centrally on the carrier strip 3 relative to a transport direction x. Defective and defect-free transponders 2 may be removably mounted on the carrier strip 3.

The transponders 2 are flat, flexible foils each carrying an unillustrated integrated circuit that has a transponder function and a film antenna. The transponders are provided on their side facing the carrier strip 3 with an unillustrated adhesive layer that allows the transponder 2 to be applied to and removed from the carrier strip 3 repeatedly.

The apparatus 1 includes a monitoring apparatus or reader 10 for detecting defective transponders 2, a transfer device in the form of a transfer roller 20 for transferring defective transponders 2 to be removed, a stripper including an upstream carrier-strip deflector 30, a downstream carrier-strip deflector 31, and a deflection roller 32 that at least partially separates each transponder 2 from the carrier strip 3 and, if it is not defective, returns it to the carrier strip 3 in a position offset from its original position, a selector in the form of a push-up roller 40 that deflects a transponder 2 that has been detected as defective and at least partially separated from the carrier strip 3 toward the transfer roller 20 in such a way that it is engaged and removed by the transfer roller 20, a controller 50 connected to the monitoring apparatus 10, the transfer roller 20, and the push-up roller 40, and a collector roller 60 that is in active connection with the transfer roller 20 for collecting defective transponders.

The operation of the apparatus 1 will be described in the following. In the operational state of the apparatus 1 shown in FIG. 1, all transponders 2 shown are defect-free, i.e. none of the transponders 2 has been removed.

The transponders 2 are continuously provided to the apparatus 1 in the transport direction x on the carrier strip 3 at a constant high speed, for example, 1.5 m/s. The reader 10 wirelessly reads the condition of a transponder 2 and transmits this condition to the controller 50. Because all of the transponders in the illustrated embodiment shown are defect free, no separation occurs, i.e. the push-up roller 40 is not actuated.

The carrier strip 3 is guided over the stripper in the form of the upstream carrier-strip deflector 30, the deflection roller 32, and the downstream carrier-strip deflector 31. The upstream carrier-strip deflector 30 has an upstream flat face 34 relative to the transport direction x of the carrier strip 3 and the downstream carrier-strip deflector 31 has a downstream flat face 35 in the transport direction x of the carrier strip 3, with a gap 33 between the upstream face 34 and the downstream face 35. The edges of the upstream and downstream faces delimiting the gap 33 run parallel. A rotational axis of the deflection roller 32 runs parallel to the edges, in the horizontal direction in the middle of the gap and offset downward in the vertical direction from the faces 34 and 35 by an amount that is approximately twice the diameter of the deflection roller 32.

As is shown in FIG. 1, the stripper causes the partial separation of the transponder 2 in a separation direction a by means of its upstream carrier-strip deflector 30 by deflecting the carrier strip 3 out of the transport direction x at the beginning of the gap 33. An edge face 36 of the carrier strip deflector 30 forms an acute angle with the face 34, with the path of the carrier strip causing the transponder 2 to peel off automatically from the carrier strip 3 and move toward the downstream carrier-strip deflector 31 via the gap 33 in the transport direction x due to its flexural rigidity. The transponder 2 is longer than the gap 33 such that it separates from the carrier strip 3 maximally by the amount established by the gap 33.

Once the transponder 2 has moved past the gap 33, its front edge reaches the downstream carrier-strip deflector 31 in a deflection section in which the carrier strip 3 is again directed in the transport direction x. As soon as the transponder 2 reaches the carrier strip 3 in the deflection section, the transponder that was separated from the carrier strip 3 in the region of the gap 33 is reapplied to the carrier strip 3 offset from its original position. The reapplication may be assisted by an unillustrated pressure roller that presses the reapplied transponder onto the carrier strip 3 and thus increases its adherence to approximately the same state as before its separation.

If a transponder 2 is defect free, it subsequently moves while being partially separated from the carrier strip 3 over the gap 33 and is placed back on the carrier strip 3 in an offset position. This process may be conducted at a high, constant carrier strip speed.

FIG. 2 shows a case at two different points in time in which a transponder 2 being moved over the gap 33 is removed, i.e. is not reapplied to the carrier strip 3.

The reader 10 wirelessly reads the condition of a transponder 2 and transmits the condition to the controller 50. Because the transponder shown being moved over the gap 33 in the illustrated embodiment is defective, it must be removed, i.e. it may not be reapplied to the carrier strip 3 after its partial separation.

For this purpose, the controller 50 controls the push-up roller 40 in such a way that, when a defective transponder 2 moves over the gap 33, it presses against a separated region of the transponder 2 from below. The transponder 2 is subsequently deflected or bent out of the transport direction x and pressed against the transfer roller 20.

The transfer roller 20 has air circulation openings 21 distributed over its outer surface that lead to the production of controllable high pressure or low pressure, with a compressed air control being provided by the control apparatus 50. In the case shown, subatmospheric pressure is being applied that causes the defective transponder 2 to adhere to the outer surface of the transfer roller 20. As shown, the transponder 2 is continuously separated from the carrier strip 3 and taken up by the transfer roller. Finally, the transponder 2 adheres completely to the transfer roller 20 due to the low pressure and is removed toward the collector roller 60 that is in active connection with the transfer roller 20.

When the transponder 2 enters the circumferential region of the collector roller 60 with the adhesive applied to its back face, the transponder 2 separates from the transfer roller 20 toward the collector roller 60. In order to support this process, the subatmospheric pressure in the region of the openings 21 may be reversed or converted into superatmospheric pressure.

The collector roller 60 is mounted on a rocker 61 that is rotationally mounted in a rotational axis 62. The defective transponders are continuously applied or adhered to the collector roller 60 such that multiple layers of transponders lying one on top of the other may build up. An increasing layer thickness is automatically compensated for by angular movement of the rocker 61. If the layer thickness exceeds a particular mass, the collector roller 60 may be exchanged for a new collector roller 60.

After removal, a blank space is formed on the carrier strip 3 into which a defect-free transponder is to be subsequently inserted. This is described with reference to FIG. 3.

FIG. 3 shows an apparatus 80 for the continuous production of a defect-free carrier strip with the apparatus 1 for continuous separation from FIG. 1. In addition to the apparatus 1 already shown in FIG. 1, the apparatus 80 includes a dispenser 70 that inserts a defect-free transponder 2 into the gaps or spaces of the carrier strip 3 from which a defective transponder 2 has been removed.

The dispenser 70 includes a supply reel 71 onto which a further carrier strip 72 has been wound on which only defect-free transponders 2 have been attached. The carrier strip 72 is guided over a deflection roller 73 and a deflector 74. Due to its shape, the deflector 74 deflects the strip in a region 75 in such a way that a transponder 2 supplied by the supply reel 71 separates from the other carrier strip 72 and is applied precisely to the carrier strip 2 in a blank space left by a previously removed transponder. The other carrier strip 72 is subsequently taken up by a winder 76. The dispenser 70 is not operated continuously, but rather is activated precisely when a transponder 2 has been removed from the carrier strip 2 by the apparatus 1.

In the transport direction x behind the dispenser 70, an unillustrated programming unit may be provided for programming the defect-free transponders 2. For example, it is possible here for manufacturer information or a product code to be written into the memory of a transponder.

In order to increase the throughput of the apparatus 80 shown in FIG. 3, the transponders 2 may be arrayed in multiple rows on the carrier strip 2.

FIG. 4 shows an apparatus 80a that has been modified for this purpose in one view in the transport direction x. The apparatus 80a is suitable for processing a carrier strip 3′ with three rows of transponders 2. Fundamentally, the apparatus 80a is the same as the apparatus 80 and functions in the same manner. However, the apparatus 80a has three selectors; each in the form of a compressed-air device 40a, 40b, and 40c, each of which is assigned to a respective row on the carrier strip 3′. Moreover, one collector roller 60a, 60b, and 60c is provided for each row.

The compressed-air devices 40a, 40b, and 40c work independently of one another because cases may occur in which, relative to the same position in the transport direction x, transponders must be removed from one row and not from another. When a transponder is selected or removed, the associated compressed-air device 40a, 40b, or 40c produces a stream of compressed air that displaces the transponder to be removed toward the transfer roller 20. A transfer and removal of the defective transponder 2 occurs in the same manner as in the apparatus 80 shown in FIG. 3.

A defective transponder 2 is subsequently applied to a collection roller 60a, 60b, or 60c associated with its row.

The illustrated embodiments shown allow a reliable production of defect-free carrier strips while operating at high speeds, with the nominal throughput optimized.

1. An apparatus for the continuous separation of defective components from a plurality of components removably mounted on at least one carrier strip in at least one continuous row, the apparatus comprising
a monitoring apparatus for detecting defective components,
a transfer device for removing defective components to be removed,
at least one stripper that separates each component at least partially from the carrier strip and reapplies it to the carrier strip in a position that is offset relative to its original position, and
at least one selector that selects a component that has been detected to be defective by the monitoring apparatus and at least partially separated from the carrier strip in such a way that it is taken up by the transfer device.

2. The apparatus according to claim wherein the stripper includes an upstream carrier-strip deflector, with the carrier strip guided over the upstream carrier-strip deflector and with the carrier strip deflector causing the partial separation of the component in the transport direction by the carrier strip being deflected from a transport direction in a separation direction.

3. The apparatus according to claim 2 wherein the stripper includes a downstream carrier-strip deflector, with the carrier strip guided over the upstream carrier-strip deflector and the downstream carrier-strip deflector, with the downstream carrier-strip deflector deflecting the carrier strip in the transport direction in an associated deflection section, and with the component that is at least partially separated from the carrier strip being reapplied to the carrier strip in the deflection section.

4. The apparatus according to claim 3 wherein the stripper includes a deflection roller with the carrier strip guided over the upstream carrier-strip deflector, the deflection roller, and the downstream carrier-strip deflector.

5. The apparatus according to claim 4 wherein the upstream carrier-strip deflector has an upstream face in a transport plane of the carrier strip and the downstream carrier-strip deflector has a downstream face in the transport plane of the carrier strip, with a gap being formed between the upstream face and the downstream face and with a rotational axis of the deflection roller being located outside the transport plane.

6. The apparatus according to claim 1 wherein the selector includes a push-up roller by means of which a defective component that has been at least partially separated from the carrier strip is deflected toward the transfer device.

7. The apparatus according to claim 1 wherein the selector includes a compressed-air device by means of which a defective component that has been at least partially separated from the carrier strip is blown toward the transfer device for selection.

8. The apparatus according to claim 1 wherein the transfer device includes a transfer roller for removing defective components.

9. The apparatus according to claim 8 wherein the transfer roller has air circulation openings distributed over its outer surface that serve to produce a controllable low pressure or high pressure that causes a defective component that has been transferred to adhere or separate.

10. The apparatus according to claim 8, further comprising:
a collector roller in an active connection with the transfer roller for accepting defective components, with a defective component being transferred from the transfer roller onto the collector roller.

11. The apparatus according to claim 1, further comprising:
a pressure roller that presses against a component that has been reapplied to the carrier strip.

12. The apparatus according to claim 1 wherein the components are arrayed on the carrier strip in multiple rows and a selector is assigned to each row.

13. An apparatus for the continuous production of a defect-free carrier strip from a carrier strip with components removably mounted thereon in a continuous fashion in at least one row, with the carrier strip having defective and defect-free components, the apparatus comprising:
an apparatus for the continuous removal of the defective components according to claim 1 and
at least one dispenser that inserts a defect-free component in spaces of the carrier strip from which a defective component has been removed.

14. The apparatus according to claim 13 wherein another carrier strip is provided on the dispenser that contains only defect-free components.

15. The apparatus according to one claim 13 wherein the components are transponders.

16. The apparatus according to claim 15, further comprising
a programming unit that programs the transponders on the defect-free carrier strip.

17. A method of the continuous production of an error-free carrier strip from a carrier strip having components arrayed thereon in at least one continuous row, with the carrier strip having defective and defect-free components, characterized by the following steps:
at least partial separation of each component from the carrier strip,
removal of a defective component that has been at least partially separated,
reapplication of a defect-free component on the carrier strip in an offset position, and
replacement of a removed component with a defect-free component.

18. The method according to claim 17 wherein a carrier strip speed is constant.
